(19) United States
(12) Patent Application Publication
(10) Pub. No.: US 2010/0089318 A1
(43) Pub. Date: Apr. 15, 2010

(54) Remote Plasma Apparatus for Manufacturing Solar Cells

(76) Inventor: Stanford R. Ovshinsky, Bloomfield Hills, MI (US)

Correspondence Address: Ovshinsky Innovation LLC, 1050 E. Square Lake Road, Bloomfield Hills, MI, 48304, US

(21) Appl. No.: 12/575,844

(22) Filed: Oct. 8, 2009

Related U.S. Application Data
(63) Continuation-in-part of application No. 12/209,699, filed on Sep. 12, 2008.
Application No. 12/209,699 is a continuation-in-part of application No. 12/316,417, filed on Dec. 12, 2008.

(51) Int. Cl. C23C 16/00

(52) U.S. Cl. 118/719; 118/723 R

(57) ABSTRACT

A continuous thin film deposition apparatus that includes a remote plasma source. The source forms a plasma from a precursor and delivers a modified form of the plasma as a charge-depleted deposition medium to a deposition apparatus for formation of a thin film material. The thin film may be formed on a continuous web or other moving substrate. The charge-depleted deposition medium may be formed within the remote plasma source and delivered to an operatively coupled deposition apparatus or the charge-depleted deposition medium may form as the plasma exits the remote plasma source. The initial plasma is formed within the remote plasma source and includes a distribution of charged species (electrons and ions). The charge-depleted deposition medium contains a reduced concentration of the charged species and permits deposition of thin film materials having lower defect concentration. In one embodiment, the thin film material is a solar material and the lower defect concentration provides a higher solar conversion efficiency.

### RELATED APPLICATION INFORMATION

This application is a continuation in part of U.S. patent application Ser. No. 12/209,699, entitled “High Speed Thin Film Deposition via Pre-Selected Intermediate” and filed on Sep. 12, 2008, the disclosure of which is hereby incorporated by reference. This application is also a continuation in part of U.S. patent application Ser. No. 12/316,417, entitled “Thin Film Deposition via a Spatially-Coordinated and Time-Synchronized Process” and filed on Dec. 12, 2008, the disclosure of which is hereby incorporated by reference.

### FIELD OF INVENTION

This invention relates to an apparatus for manufacturing solar materials that includes a remote plasma source. More particularly, this invention relates to a continuous deposition apparatus that utilizes a remote plasma source. Most particularly, this invention relates to continuous production of multilayer solar materials via a remote plasma source.

### BACKGROUND OF THE INVENTION

Concern over the depletion and environmental impact of fossil fuels has stimulated strong interest in the development of alternative energy sources. Significant investments in areas such as batteries, fuel cells, hydrogen production and storage, biomass, wind power, algae, and solar energy have been made as society seeks to develop new ways of creating and storing energy in an economically competitive and environmentally benign fashion. The ultimate objective is to minimize society's reliance on fossil fuels and to do so in an economically competitive way that minimizes greenhouse gas production.

A number of experts have concluded that to avoid the serious consequences of global warming, it is necessary to maintain CO₂ at levels of 550 ppm or less. To meet this target, based on current projections of world energy usage, the world will need 17 TW of carbon-free energy by the year 2050 and 33 TW by the year 2100. The estimated contribution of various carbon-free sources toward the year 2050 goal are summarized below:

| | Projected Energy |
|---|---|
| Source | Supply (TW) |
| Wind | 2-4 |
| Tidal | 2 |
| Hydro | 1.6 |
| Biofuels | 5-7 |
| Geothermal | 2-4 |
| Solar | 600 |

Based on the expected supply of energy from the available carbon-free sources, it appears that solar energy is the only viable solution for reducing greenhouse emissions and alleviating the effects of global climate change.

Amorphous semiconductors are attractive materials for solar energy applications. Unlike crystalline silicon, for example, amorphous silicon is a direct gap material with high absorption efficiency of much of the solar spectrum. As a result, lightweight and efficient solar cells based on thin layers of amorphous silicon are possible. The instant inventor has long recognized the advantages of amorphous silicon and related materials as solar cell materials and has been instrumental in developing automated and continuous manufacturing techniques for producing solar and photovoltaic devices based on amorphous semiconductors or combinations of amorphous semiconductors with nanocrystalline, microcrystalline, or polycrystalline semiconductors.

Representative discoveries of the instant inventor in the field of amorphous semiconductors and photovoltaic materials include U.S. Pat. Nos. 4,400,409 (describing a continuous manufacturing process for making thin film photovoltaic films and devices); 4,410,588 (describing an apparatus for the continuous manufacturing of thin film photovoltaic solar cells); 4,438,723 (describing an apparatus having multiple deposition chambers for the continuous manufacturing of multilayer photovoltaic devices); 4,217,374 (describing suitability of amorphous silicon and related materials as the active material in several semiconducting devices); 4,226,898 (demonstration of solar cells having multiple layers, including n- and p-doped); 5,103,284 (deposition of nanocrystalline silicon and demonstration of advantages thereof); and 5,324,553 (microwave deposition of thin film photovoltaic materials). The instant inventor has also presented his work in numerous scientific articles, including “The material basis of efficiency and stability in amorphous photovoltaics” (Solar Energy Materials and Solar Cells, vol. 32, p. 443-449 (1994); and “Amorphous and disordered materials—The basis of new industries” (Materials Research Society Symposium Proceedings, vol. 554, p. 399-412 (1999).

Current efforts in photovoltaic material manufacturing are directed at increasing the deposition rate. Higher deposition rates lower the cost of thin film solar cells and lead to a decrease in the unit cost of electricity obtained from solar energy. As the deposition rate increases, thin film photovoltaic materials become increasingly competitive with fossil fuels as a source of energy. Presently, PECVD (plasma-enhanced chemical vapor deposition) is the most cost-effective method for the commercial-scale manufacturing of amorphous silicon and related solar energy materials. Current PECVD processes provide uniform coverage of large-area substrates with device quality photovoltaic material at a deposition rate of ˜5 [symbol] /s.

In order to enhance the economic competitiveness of plasma deposition processes, it is desirable to increase the deposition rate. The deposition rate of prevailing plasma deposition techniques is limited by the high concentration of intrinsic defects that develops in amorphous solar materials as the deposition rate is increased. The intrinsic defects include structural defects such as dangling bonds, strained bonds, unpassivated surface states, non-tetrahedral bonding distortions, coordinatively unsaturated silicon or germanium. The structural defects create electronic states in the bandgap of the amorphous semiconductors that detract from solar conversion efficiency by promoting nonradiative recombination processes that deplete the concentration of free carriers generated by absorbed sunlight. Intrinsic defects are also believed to contribute to degradation of solar cell performance through the Staebler-Wronski effect.

The instant inventor has previously demonstrated that the concentration of intrinsic defects that forms in a plasma-deposited material depends on the distribution of species present in the plasma. A plasma is a complex state of matter that includes ions, ion-radicals, neutral radicals and molecules in multiple energetic states. The instant inventor has shown that charged species are generally detrimental to the quality of as-deposited amorphous semiconductors because they promote the creation of defects. Charged species tend to strike the deposition surface with high kinetic energy and as a result, tend to damage a growing thin film material through bond cleavage. Neutral species, in contrast, tend to promote more uniform bonding and accordingly lead to lower defect concentrations in as-deposited material.

To minimize the concentration of intrinsic defects, current plasma deposition processes are performed at low deposition rates. By slowing the deposition process, the intrinsic defects that form in the as-deposited material have the opportunity to equilibrate to energetically-favored states that have more regular bonding configurations. As a result, the concentration of intrinsic defects is reduced. Unfortunately, the reduced deposition rate impairs the economic competitiveness of the process.

A need exists for a plasma deposition process that is designed to preferentially deliver neutral species of a plasma to a deposition process. A deposition process based on the preferential delivery of neutral species will minimize the creation of intrinsic defects in as-deposited amorphous semiconductors and provide higher deposition rates.

### SUMMARY OF THE INVENTION

This invention provides an apparatus for the plasma or plasma-assisted deposition of thin film materials. The apparatus receives a precursor gas and converts it into a charge-depleted deposition medium that is used in the formation of a thin film material. The charge-depleted deposition medium provides a more favorable distribution of species for forming thin film materials having a low defect concentration.

In one embodiment, the apparatus includes a remote plasma source that includes two internal electrodes for forming a plasma (or thermal plasma) from a deposition precursor. The deposition precursor is introduced into the remote plasma source, enters the plasma region, and is activated to plasma. The deposition precursor subsequently exits that plasma region and deactivates to form an energized, but charge-depleted deposition medium. The charge-depleted deposition medium and is then delivered to a deposition chamber for deposition of a thin film material on a substrate. The remote plasma source and deposition chamber may be interconnected by an orifice or nozzle.

In another embodiment, the apparatus includes a remote plasma source that includes an internal electrode and a backplane electrode for forming a plasma from a deposition precursor. The deposition precursor is introduced into the remote plasma source, enters the plasma region, and is activated to plasma. The deposition precursor subsequently exits that plasma region and deactivates to form an energized, but charge-depleted deposition medium. The charge-depleted deposition medium and is then delivered to a deposition chamber for deposition of a thin film material on a substrate. The backplane electrode forms a boundary between the remote plasma source and the deposition chamber and includes an orifice or nozzle for delivering the charge-depleted deposition medium to the deposition chamber. In a further embodiment, a nozzle interconnecting the remote plasma source and deposition chamber may serve as an electrode for forming a plasma from the deposition precursor.

In a further embodiment, the deposition chamber includes a remote plasma source for forming a plasma from a background or carrier gas. The background or carrier gas enters the plasma region of the remote plasma source, is activated to a plasma state, and subsequently deactivated to form a charge-depleted medium that is delivered from the remote plasma source to an interconnected deposition chamber. The deposition chamber includes an inlet for delivery of a deposition precursor. The deposition precursor is delivered to the deposition chamber instead of the remote plasma source, but is introduced in close proximity to the point at which the charge-depleted background or carrier gas is provided by the remote plasma source to the deposition chamber. The charge-depleted background or carrier gas is in an excited state and energizes the deposition precursor to form a charge-depleted deposition medium within the deposition chamber that is used to form a thin film material on a substrate.

The deposition apparatus may include one or more deposition chambers to form one or more thin film materials. Thin film materials achievable with the instant deposition apparatus include n-type materials, p-type material, and i-type materials. The materials may be formed individually or as a stack. The substrate used in the deposition apparatus may be stationary or moving. Moving substrates include continuous web substrates and may be delivered by a payout roller to one or more deposition chambers. A take up roller may receive the moving substrate from the last of the one or more deposition chambers.

### BRIEF DESCRIPTION OF THE DRAWING

FIG. 1 depicts the range of species potentially produced from silane in a plasma.

FIG. 2 depicts a deposition apparatus that includes a remote plasma source with two internal electrodes for delivering a charge-depleted deposition medium to a substrate for formation of a thin film material.

FIG. 3 depicts a deposition apparatus that includes a remote plasma source with an internal electrode and a backplane electrode for delivering a charge-depleted deposition medium to a substrate for formation of a thin film material.

FIG. 4 depicts a deposition apparatus that includes a remote plasma source with an internal electrode and nozzle for delivering a charge-depleted deposition medium to a substrate for formation of a thin film material.

FIG. 5 depicts an adaptation of the deposition apparatus shown in FIG. 4 that includes a moving continuous web substrate.

FIG. 6 depicts an adaptation of the deposition apparatus shown in FIG. 5 that includes a plurality of deposition chambers.

### DETAILED DESCRIPTION OF THE ILLUSTRATED EMBODIMENTS

Although this invention will be described in terms of certain preferred embodiments, other embodiments that are apparent to those of ordinary skill in the art, including embodiments that do not provide all of the benefits and features set forth herein and including embodiments that provide positive benefits for high-volume manufacturing, are also within the scope of this invention. Accordingly, the scope of the invention is defined only by reference to the appended claims.

This invention provides a deposition apparatus for manufacturing thin film materials, including amorphous semiconductors, at high rates of production. The apparatus includes a plasma source remote from the substrate. The remote plasma source generates a plasma external to a deposition chamber, without using the substrate as an electrode for plasma generation. The plasma exits the remote plasma source and is delivered in a state depleted in charged particles (ions and electrons) to a moving substrate for deposition of a thin film material. The deposition apparatus may further include additional deposition chambers for producing additional layers to permit continuous manufacturing of multilayer solar materials or devices.

The instant invention recognizes that the plasmas used in prior art deposition processes include species that promote the formation of defects in thin film materials, including solar and photovoltaic materials. A conventional plasma is a random and chaotic state of matter that includes a distribution of charged and neutral species. The species may originate from deposition precursors or carrier gases and are in an energized state. The plasma may include neutral molecules, charged molecules, or fragments of molecules. The molecular fragments are metastable species that include ions, ion-radicals and neutral radicals derived from molecules of a deposition precursor or carrier gas.

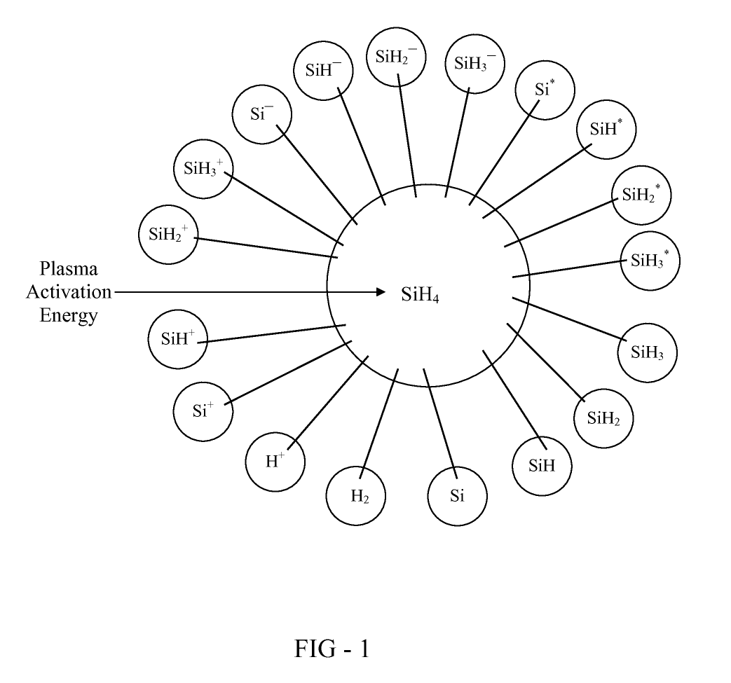

By way of example, the plasma deposition of amorphous silicon most commonly occurs by forming a plasma from silane (SiH₄). FIG. 1 depicts the species that may be generated in a silane plasma. The potential species include a variety of ions, radicals and molecular species. The radicals include neutral or charged forms of SiH₃, SiH₂, SiH, Si, and H. The species may be in a ground electronic state or an excited electronic state (designated by an asterisk (e.g. SiH* is a neutral radical in an excited electronic state)). The number density and excitation energy required for the formation of selected species in a conventional silane plasma have been reported and are listed below.

| Species | Type | Energy (eV) | Number Density (cm⁻³) |
|---|---|---|---|
| SiHₓ⁺ | ground state ion | >13.6 | ~10⁸ |
| | or ion-radical | | |
| Si* | excited state | 10.53 | ~10⁵ |
| | neutral radical | | |
| Si | ground state | 10.36 | ~10⁸-10⁹ |
| | neutral radical | | |
| SiH* | excited state | 10.33 | ~10⁵ |
| | neutral radical | | |
| SiHₓ⁻ | ground state ion | ~10 | ~10⁸ |
| | or ion-radical | | |
| SiH | ground state | 9.47 | ~10⁸-10⁹ |
| | neutral radical | | |
| SiH₂ | ground state | 9.47 | ~10⁹ |
| | neutral radical | | |
| SiH₃ | ground state | 8.75 | ~10¹² |
| | neutral radical | | |
| SiH₄ | molecule | 0 | ~10¹⁵ |

One of the limitations of conventional plasma deposition processes is an inability to adequately control the identity and abundance of the different species in the plasma. The need to control the characteristics of the plasma arises because some of the species present in the plasma are essential or beneficial to the deposition of the intended thin film material, while other species are detrimental. The origin of the detrimental effect of particular species on film properties may be chemical or physical in nature. In the case of the deposition of amorphous silicon from silane, for example, the neutral radical SiH₂ is thought to be detrimental because its incorporation into the as-deposited material creates dihydride defects that compromise solar efficiency through nonradiative processes that deplete photogenerated charge carriers.

Detrimental chemical interactions that alter the distribution of species may also occur within the plasma. In the deposition of amorphous silicon from silane, for example, the neutral radical SiH₃ is believed to be the most favorable deposition species. Chemical interactions that cause SiH₃ to transform to other species before deposition are therefore undesired. Examples of such detrimental chemical interactions include hydrogen abstraction reactions that occur between high energy hydrogen-depleted plasma species (such as Si or SiH) and SiH₃. Hydrogen abstraction reactions are particularly detrimental because they deplete the concentration of the preferred SiH₃ deposition species and transform it to the deleterious SiH₂ species.

Physical interactions between plasma species and a depositing thin film may also impair the performance or properties of the thin film. The most problematic physical interactions are collisions that occur between plasma species and the thin film during film growth. Collisions lead to damage (e.g. bond breakage, ejection of atoms) and the formation of structural and electronic defects (e.g. dangling bonds, irregular coordination or configuration) in the as-deposited thin film material that diminish solar or photovoltaic conversion efficiency by providing non-radiative decay channels that deplete photogenerated charge carriers.

Charged species (ions or electrons) are particularly likely to collide with the as-deposited thin film because of coulombic interactions that occur between charged species and the charged electrodes used to initiate the plasma. Since the substrate (and as-deposited thin film) is normally in electrical communication with one of the electrodes (usually the anode) in a conventional plasma deposition process, the substrate tends to acquire a charge and thus attracts oppositely charged species from the plasma. Strong coulombic interactions impart high kinetic energy to the charged plasma species attracted to the substrate and lead to particularly energetic collisions with the as-deposited thin film.

To avoid detrimental chemical and physical interactions between species in the plasma phase or between plasma species and the as-deposited thin film, it is desirable to achieve control over the composition and distribution of species in the plasma. While some degree of control is available in the prior art through variations in process parameters such as temperature, pressure, concentration of precursors, type of precursors, flow rate, and electron temperature of the plasma, greater control is needed to improve the solar or photovoltaic efficiency of thin film materials (especially at high deposition rates). Current methods of forming a plasma provide only coarse control over the state of the plasma. This invention provides for finer control over the species generated in a plasma that are permitted to participate in the thin film deposition process.

In one embodiment, the instant apparatus uses a remote plasma source that activates one or more deposition precursors to form a deposition medium and directs the deposition medium to a substrate or deposition chamber. The activated one or more deposition precursors are energized to a high energy state. The high energy state may be an electronic excited state or an ionized excited state. In one embodiment, the activated one or more deposition precursors are a plasma. In another embodiment, the activated one or more deposition precursors are a thermal plasma. The remote plasma source may include a plasma region in which a plasma or thermal plasma is formed from one or more deposition precursors. The plasma or thermal plasma may be directed to a deposition chamber or substrate as a deposition medium for deposition of a thin film material. In an alternative embodiment, the one or more deposition precursors may deactivate to a lower energy state upon exiting the plasma region and may be directed to a deposition chamber or substrate as a deposition medium in a deactivated state.

In one embodiment, the instant apparatus uses a remote plasma source that forms a plasma from one or more deposition precursors, reduces the concentration of charged species (ions and/or electrons) to form a deposition medium and delivers the charge-depleted deposition medium to the deposition process. The charge-depleted deposition medium is subsequently used to form a thin film material on a moving substrate in the deposition apparatus. By utilizing a deposition medium in a charge-depleted state, the concentration of defects in the deposited thin film material is reduced and better conversion efficiency is obtained.

In this embodiment, reduction in the concentration of charged species occurs internally within the remote plasma source and the deposition medium exiting the remote plasma source is depleted in charged species. The remote plasma source includes an anode and cathode between which a voltage is applied. The remote plasma source further includes an inlet for receiving a deposition precursor and an outlet for delivering a charge-depleted deposition medium to a deposition chamber. A plasma is formed within the remote plasma source from the deposition precursor in the region between the anode and cathode. The region between the anode and cathode may be referred to herein as the plasma region of the remote source. The outlet is spaced apart from the plasma region.

The deposition precursor is supplied to the plasma region as a flowing stream and has kinetic energy of motion. The motion of the deposition precursor is preferably directed toward the outlet. The deposition precursor remains in motion as it is converted to a plasma in the plasma region and exits the plasma region in a moving state. When the plasma exits the plasma region, it deactivates to a lower energy state. The deactivated state may possess a reduced concentration of charged species and may be viewed as a modified form of the initial plasma. In one embodiment, this modified plasma constitutes a charge-depleted deposition medium that may be transported from the remote plasma source to a substrate for deposition of a thin film material.

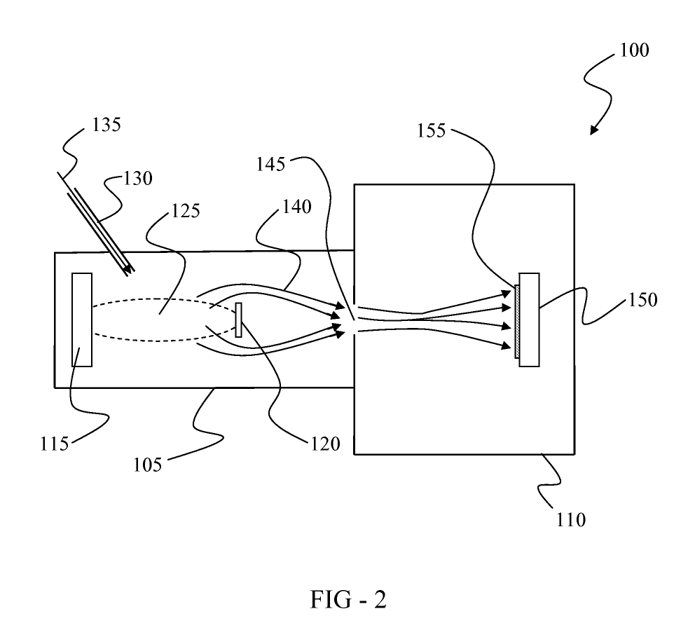

FIG. 2 depicts a deposition apparatus in accordance with this embodiment of the instant invention. Deposition apparatus 100 includes remote plasma source 105 interconnected to deposition chamber 110. Remote plasma source 105 includes first electrode 115 and second electrode 120 with plasma region 125 formed therebetween. Remote plasma source 105 further includes inlet 130 for delivering deposition precursor 135. Deposition precursor 135 enters plasma region 125 and exits as deactivated medium 140 that enters deposition chamber 110 through opening 145. Deactivated medium 140 is charge depleted and continues toward substrate 150 whereupon thin film material 155 is formed.

A pressure differential between remote plasma source 105 and deposition chamber may facilitate motion of deactivated medium 140. If the pressure within deposition chamber 110 is less than the pressure within remote plasma source 105, deactivated medium 140 is accelerated toward substrate 150 as it exits opening 145. In one embodiment, the pressure within deposition chamber 110 is at least a factor of 10 less than the pressure within remote plasma source 105. In another embodiment, the pressure within deposition chamber 110 is at least a factor of 100 less than the pressure within remote plasma source 105. In a further embodiment, the pressure within deposition chamber 110 is at least a factor of 1000 less than the pressure within remote plasma source 105.

In another embodiment, the deactivated plasma is further modified before exiting the remote plasma source to further reduce the concentration of charged species. In this embodiment, the outlet of the remote plasma source is configured as a restricted orifice, such as a nozzle, that acts to confine the deactivated plasma. In the embodiment of FIG. 2, for example, opening 145 may be constricted to form a narrow orifice or equipped with a nozzle to regulate the flow of deactivated deposition medium 140 into deposition chamber 110. Confinement constricts the volume of the deactivated plasma and reduces the average separation between species in the deactivated plasma. The reduced separation promotes interactions between species. While not wishing to be bound by theory, the instant inventor believes that confinement particularly promotes collisions between charged species that have the effect of extinguishing charged species through a conversion to neutral species. As a result, charge depletion of the deposition medium exiting the remote plasma source is enhanced.

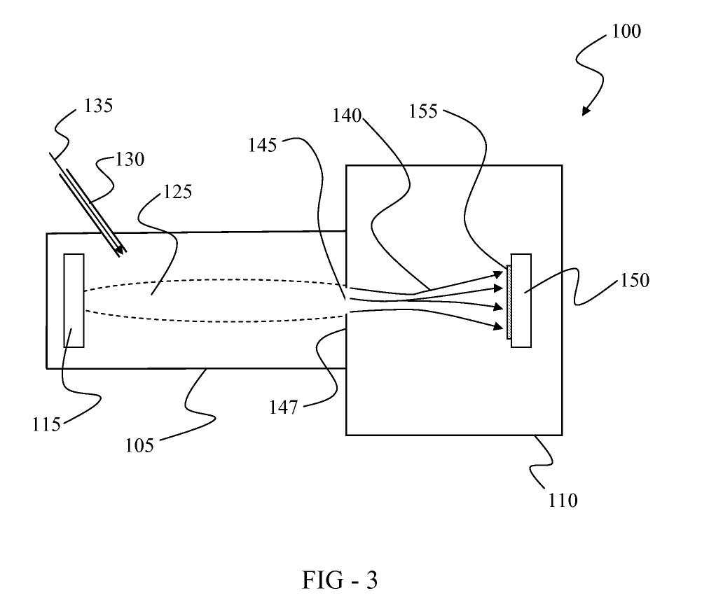

FIG. 3 shows a modification of the embodiment shown in FIG. 2 in which second electrode 120 is removed and instead, backplane 147 of remote plasma source 105 is used as an electrode in the formation of plasma region 125. As in the embodiment of FIG. 2, opening 145 may be constricted to confine the plasma as it exits remote plasma source 105 and deactivates to form charge-depleted deposition medium 140 upon entry into deposition chamber 110. Opening 145 may also be fitted with a nozzle. The nozzle may serve as an electrode in combination with backplane 147 or may function as an electrode independent of backplane 147.

By controlling the flow rate of the precursor, the concentration or state of dilution of the precursor, the electric field strength used to generate the initial plasma, the pressure within the remote plasma source and the diameter of the outlet orifice or nozzle, it is possible to control the degree to which the initial plasma becomes depleted in charged species. In one embodiment, the concentration of charged species in the modified plasma delivered as a charge-depleted deposition medium is less than 100 ppm. In another embodiment, the concentration of charged species is less than 10 ppm. In a further embodiment, the concentration of charged species is less than 1 ppm.

In another embodiment, the remote plasma source forms a plasma from an inert or background gas and the plasma state is maintained at the outlet of the remote source. Representative inert or background gases include argon, krypton, helium, hydrogen, neon, or nitrogen. One way to maintain the plasma state at the outlet is to utilize the outlet (or surrounding structure or integrated nozzle) as an electrode in the plasma generation process.

Charge depletion of the plasma is achieved in this embodiment by maintaining a pressure differential between the remote plasma source and an interconnected deposition chamber. The pressure within the remote plasma source is kept high and the pressure within the deposition chamber is kept low. In a typical configuration, the pressure in the remote plasma source may be ˜0.1-1 bar and the pressure in the deposition chamber may be maintained at ˜0.1-1 mbar. The pressure differential causes the plasma to expand as it exits the remote source and enters the deposition chamber. As the plasma expands, it accelerates, experiences a reduction in electron temperature and deactivates to a charge-depleted state.

The deposition precursor is not delivered to the remote plasma source in this embodiment, but rather is provided to the deposition chamber at a position external to the remote plasma source. In one embodiment, the deposition precursor is delivered in the vicinity of the expanding deactivated plasma as it exits the remote plasma source. Although charge-depleted and deactivated, the medium exiting the remote plasma source remains energized and includes numerous species in excited electronic states. The charge-depleted deactivated plasma also has high kinetic energy of motion. As a result, interaction of the charge-depleted deactivated plasma with the deposition precursor energizes the deposition precursor to form a deposition medium. Since the medium exiting the remote plasma source is less energized than a conventional plasma and charge-depleted relative to a conventional plasma, the deposition medium that forms from the precursor is also less energized and charge-depleted relative to a conventional plasma. This charge-depleted deposition medium is directed to a substrate for thin film deposition.

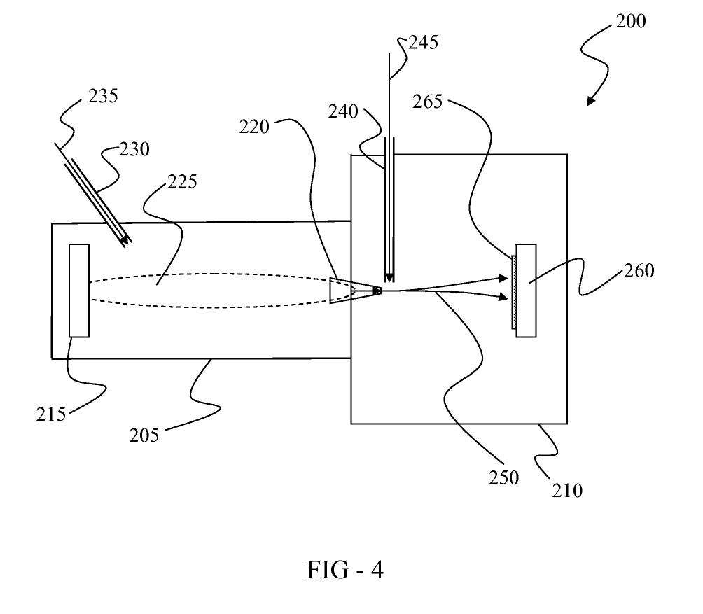

FIG. 4 depicts a deposition apparatus in accordance with this embodiment. Deposition apparatus 200 includes remote plasma source 205 interconnected to deposition chamber 210 via nozzle 220. Remote plasma source 205 includes first electrode 215 and utilizes nozzle 220 as a second electrode to form plasma region 225. Remote plasma source 205 further includes inlet 230 for delivering background gas 235. Deposition chamber further includes inlet 240 for delivering deposition precursor 245. Background gas 235 enters plasma region 225, exits nozzle 220 and mixes with deposition precursor 245 to form charge-depleted deposition medium 250. Charge-depleted deposition medium 250 is directed toward substrate 260 for formation of thin film material 265. Corresponding embodiments in which remote plasma source 205 is interconnected to deposition chamber 210 via an opening or orifice are within the scope of the instant invention as are embodiments in which remote plasma source includes an internal second electrode (as shown in FIG. 2 hereinabove) or a backplane electrode (as shown in FIG. 3 hereinabove).

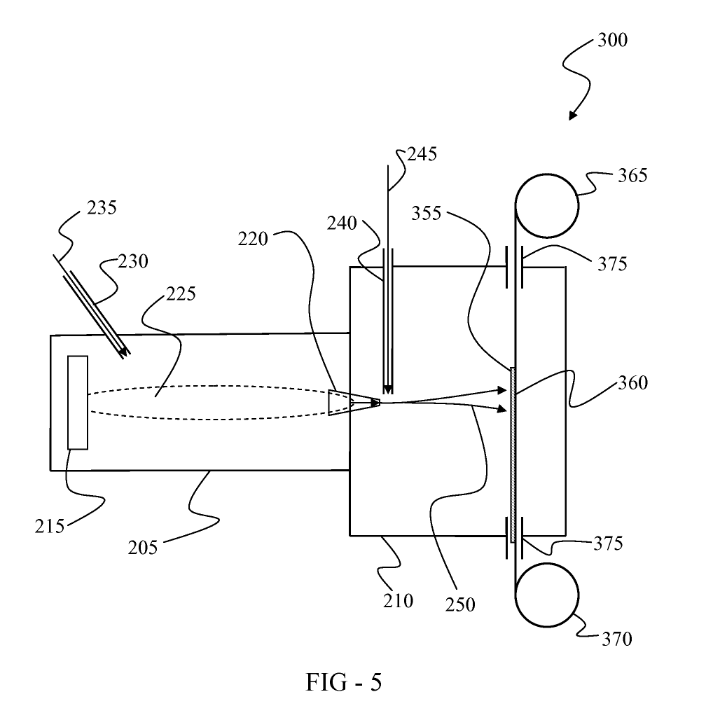

FIG. 5 shows an adaptation of FIG. 4 that includes a continuous web substrate. In FIG. 5, substrate 260 shown in FIG. 4 has been replaced by continuous web substrate 360. Continuous web substrate 360 is in motion during deposition and is delivered to deposition chamber 210 by payout roller 365 and received by take up roller 370 after deposition of thin film material 355. Continuous web substrate 360 enters and exits deposition chamber 210 through isolation devices 375. Isolation devices 375 may be, for example, gas gates.

Deposition precursors suitable for use with the instant deposition apparatus include silane (SiH₄), fluorinated forms of silane (SiF₄, SiF₃H, SiF₂H₂, SiFH₃), germane (GeH₄), and fluorinated forms of germane (GeF₄, GeF₃H, GeF₂H₂, GeFH₃). The advantages of fluorine have been amply demonstrated by S. R. Ovshinsky. In particular, S. R. Ovshinsky has shown that the inclusion of fluorine promotes the regular coordination of silicon, germanium and other constituents of thin film materials, acts to passivate dangling bonds and other defects, and in appropriate quantities, acts to promote the formation of nanocrystalline, intermediate range order, or microcrystalline phases of silicon and germanium. (For more information see, for example, the following references by S. R. Ovshinsky: U.S. Pat. No. 5,103,284 (formation of nanocrystalline silicon from SiH₄ and SiF₄); U.S. Pat. No. 4,605,941 (showing substantial reduction in defect states in amorphous silicon prepared in presence of fluorine); and U.S. Pat. No. 4,839,312 (presents several fluorine-based precursors for the deposition of amorphous and nanocrystalline silicon)).

Gas-phase doping precursors to achieve n-type or p-type doping may also be utilized in conjunction with one or more deposition precursors. Doping precursors include gas phase compounds of boron (e.g. boranes or organoboranes), phosphorous (e.g. phosphine or organophosphines), and arsenic (e.g. arsine or organoarsines). One or more deposition or doping precursors may be introduced to the remote plasma source or deposition chamber individually, sequentially, or in combination.

The instant deposition apparatus may be used to form amorphous, nanocrystalline, microcrystalline, or polycrystalline materials, or combinations thereof in a single layer or multiple layer structures. In one embodiment, the instant deposition apparatus includes a plurality of deposition chambers, where at least one of the deposition chambers is equipped with a remote plasma source having the capabilities described hereinabove. The different chambers may form materials of different composition, different doping, and/or different crystallographic form (amorphous, nanocrystalline, microcrystalline, or polycrystalline)

The instant deposition apparatus is adapted to deposit one or more thin film materials on a continuous web or other moving substrate. In one embodiment, a continuous web substrate or other moving substrate is advanced through each of a plurality of deposition chambers and a sequence of layers is formed on the moving substrate. The individual deposition chambers within the plurality are operatively interconnected and environmentally protected to protect intermixing of the deposition media formed or introduced into the individual chambers. Gas gates, for example, may be placed between the chambers to prevent intermixing. A variety of multiple layer or stacked cell device configurations may be obtained.

As used herein, a layer is referred to as being formed on a moving substrate if the layer is mechanically supported by the substrate. A layer may be formed on a substrate even though an intervening layer is present between the layer and the substrate. As an example, a bare moving substrate may be introduced into the first deposition chamber of a plurality of deposition chambers and a first thin film material may be formed on the bare substrate. This first layer makes direct or physical contact with the moving substrate. If the moving substrate is advanced to a second deposition chamber, a second thin film material may be formed on the first thin film material. The second thin film material makes direct or physical contact with the first thin film material and may be referred to herein as being formed on the first thin film material or as being formed on the moving substrate.

One important photovoltaic device is the triple junction solar cell, which includes a series of three stacked n-i-p devices with graded bandgaps on a common substrate. The graded bandgap structure provides more efficient collection of the solar spectrum. In making an n-i-p photovoltaic device, a first chamber is dedicated to the deposition of a layer of an n-type semiconductor material, a second chamber is dedicated to the deposition of a layer of substantially intrinsic (i-type) semiconductor material, and a third chamber is dedicated to the deposition of a layer of a p-type semiconductor material. In one embodiment, the intrinsic semiconductor layer is an amorphous semiconductor that includes silicon, germanium, or an alloy of silicon and germanium. The n-type and p-type layers may be microcrystalline or nanocrystalline forms of silicon, germanium, or an alloy of silicon and germanium. The process can be repeated by expanding the deposition apparatus to include additional chambers to achieve additional n-type, p-type, and/or i-type layers in the structure. A triple cell structure, for example, can be achieved by extending the apparatus to include six additional chambers to form a second and third n-i-p structure on the web. Tandem devices and devices that include p-n junctions are also within the scope of the instant invention.

In most device designs, the intrinsic layer of an n-i-p stack of layers is responsible for most of the absorption of the incident solar (or other electromagnetic) spectrum and conversion of the incident spectrum to charge carriers. In practice, the thickness of the intrinsic layer in the n-i-p stack is much greater than the thickness of the surrounding n-type and p-type layers. As a result, the presence of defects is particularly problematic in the intrinsic layer. Accordingly, in one embodiment of the instant invention, the deposition chamber used to form the intrinsic layer of a multilayer stack is equipped with a remote plasma source and operated as described hereinabove to provide an intrinsic layer having a low defect concentration.

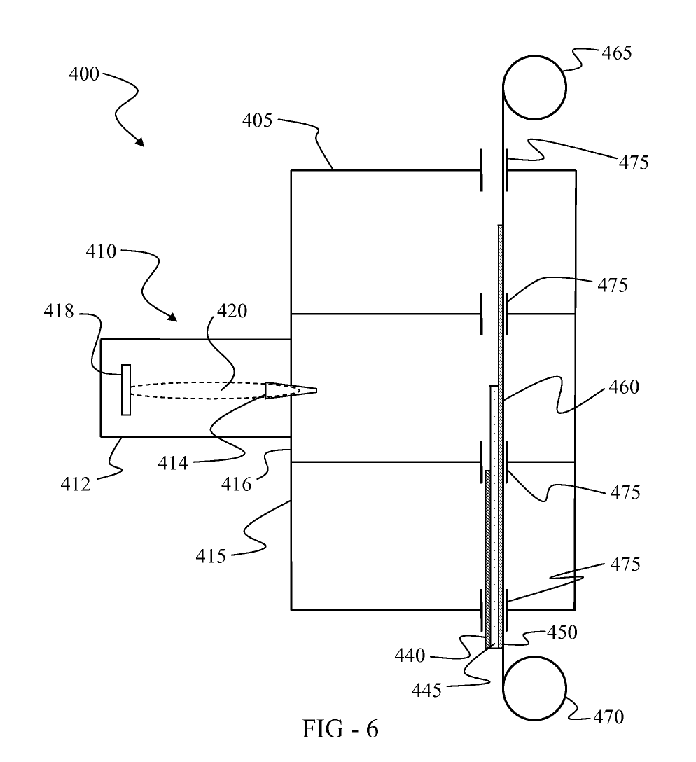

FIG. 6 depicts an expansion of the apparatus shown in FIG. 5 to include two additional deposition chambers. Apparatus 400 includes payout roller 465 for delivering moving continuous web substrate chamber 460 to a three-chamber system adapted for the formation of an n-i-p structure. Apparatus 400 further includes take up roller 470 for receiving moving substrate 460. The three-chamber system of apparatus 400 includes chamber 405 for depositing p-type layer 440, chamber 410 for depositing i-type layer 445, and chamber 415 for depositing n-type layer 450 on moving substrate 460. Chamber 410 is analogous to apparatus 300 shown in FIG. 5 and includes remote plasma source 412 interconnected to secondary chamber 416 via nozzle 414. Remote plasma source 412 includes first electrode 418 and utilizes nozzle 414 as a second electrode to form plasma region 420 as described hereinabove in connection with FIGS. 4 and 5. (The inlets, precursor stream, background gas stream, and charge-depleted deposition medium depicted in FIGS. 4 and 5 are omitted in FIG. 6 for clarity.) Gas gates 475 separate the chambers and insure isolation of the individual chambers. Chamber 415 and chamber 405 may deposit n-type and p-type materials, respectively, using a conventional plasma technique from silicon, germanium, fluorinated etc. precursors such as those described hereinabove.

Bandgap grading of multiple junction device structures may be achieved by modifying the composition of the intrinsic (i-type) layer in the separate n-i-p subunits. In one embodiment, the highest bandgap in the triple junction cell results from incorporation of amorphous silicon as the intrinsic layer in one of the n-i-p structures. Alloying of silicon with germanium to make amorphous silicon-germanium alloys leads to a reduction in bandgap. The second and third n-i-p structures of a triple junction cell may include intrinsic layers comprising SiGe alloys having differing proportions of silicon and germanium. In this way, each of the three intrinsic layers of a triple cell device has a distinct bandgap and each bandgap can be optimized to absorb a particular portion of the incident solar or electromagnetic radiation.

In one device configuration, the incident radiation first encounters an n-i-p structure that includes an amorphous silicon intrinsic layer. The amorphous silicon intrinsic layer absorbs the shorter wavelength fraction of the incident radiation (e.g. shorter wavelength visible and ultraviolet wavelengths) and transmits the longer wavelength fraction (e.g. middle and longer wavelength visible and infrared wavelengths). The longer wavelength fraction next encounters a second intrinsic layer that includes a silicon-germanium alloy having a relatively lower germanium content. The second intrinsic layer absorbs the shorter wavelength portion (e.g. middle wavelength visible portion) of the longer wavelength fraction transmitted by the amorphous silicon intrinsic layer and transmits the longer wavelength portion (e.g. long wavelength visible and infrared wavelengths) to a third intrinsic layer having an intrinsic layer that includes a silicon-germanium alloy with a relatively higher germanium content. By grading the bandgaps of the intrinsic layers, more efficient absorption of the incident radiation occurs and better conversion efficiency is achieved.

In addition to compositional variation, bandgap modification may also be achieved through control of the microstructure of the intrinsic layer. Polycrystalline silicon, for example, has a different bandgap than amorphous silicon and multilayer stacks of various structural phases may be formed with the instant continuous web apparatus. The nanocrystalline and intermediate range order forms of silicon can provide bandgaps between the bandgap of crystalline silicon and the bandgap of amorphous silicon.

Another important multilayer structure is the p-n junction. In conventional amorphous silicon or hydrogenated amorphous silicon, the hole mobility is too low to permit efficient operation of a p-n junction. The low hole mobility is a consequence of a high defect density that leads to efficient trapping of charge carriers before they can be withdrawn as external current. To compensate for carrier trapping, an i-layer is often included in the structure. With the material prepared by the instant invention, the defect concentration in n-type or p-type material is greatly reduced and efficient p-n junctions can be formed from silicon, germanium, and silicon-germanium alloys. Alternatively, p-i-n structure can be formed in which the i-layer thickness necessary for efficient charge separation is much smaller that is required for current devices.

Those skilled in the art will appreciate that the methods and designs described above have additional applications and that the relevant applications are not limited to the illustrative examples described herein. The present invention may be embodied in other specific forms without departing from the essential characteristics or principles as described herein. The embodiments described above are to be considered in all respects as illustrative only and not restrictive in any manner upon the scope and practice of the invention. It is the following claims, including all equivalents, which define the true scope of the instant invention.

We claim:

1. A thin film deposition apparatus comprising:
a first deposition chamber;
a first remote plasma source operatively connected to said first deposition chamber, said remote plasma source receiving a first deposition precursor, said first remote plasma source forming a first deposition medium from said first deposition precursor; and
a substrate in motion in said first deposition chamber, said moving substrate being spaced apart from said first remote plasma source, said first remote plasma source directing said first deposition medium into said first deposition chamber and toward said moving substrate, said first deposition medium forming a first thin film material on said moving substrate.

2. The deposition apparatus of claim 1, wherein said first remote plasma source is operatively connected to said first deposition chamber with an orifice, said first remote plasma source directing said first deposition medium into said first deposition chamber through said orifice.

3. The deposition apparatus of claim 2, wherein said first remote plasma source is operatively connected to said first deposition chamber with a nozzle, said nozzle including said orifice.

4. The deposition apparatus of claim 1, wherein said first deposition precursor comprises silicon, germanium, hydrogen, or fluorine.

5. The deposition apparatus of claim 4, wherein said first deposition precursor comprises silane, fluorinated silane, disilane, fluorinated disilane, germane or fluorinated germane.

6. The deposition apparatus of claim 1, wherein said first thin film material includes amorphous regions.

7. The deposition apparatus of claim 1, wherein said first thin film material includes nanocrystalline or microcrystalline regions.

8. The deposition apparatus of claim 1, wherein said first thin film material is an intrinsic semiconductor.

9. The deposition apparatus of claim 1, wherein said first thin film material is an n-type or p-type semiconductor.

10. The deposition apparatus of claim 1, wherein said first remote plasma source includes a first electrode and a second electrode, said first remote plasma source including a first plasma region between said first electrode and said second electrode, said first remote plasma source activating said first deposition precursor in said first plasma region, said activated first deposition precursor exiting said first plasma region, said exiting first deposition precursor providing said first deposition medium.

11. The deposition apparatus of claim 10, wherein said first remote plasma source is operatively connected to said first deposition chamber with a nozzle, said nozzle including said orifice.

12. The deposition apparatus of claim 11, wherein said first electrode comprises said orifice.

13. The deposition apparatus of claim 10, wherein said activated first deposition precursor comprises a plasma.

14. The deposition apparatus of claim 13, wherein said plasma is a thermal plasma.

15. The deposition apparatus of claim 10, wherein said activated first deposition precursor deactivates upon said exiting said first plasma region, said first deposition medium comprising said deactivated first deposition precursor.

16. The deposition apparatus of claim 10, wherein said activated first deposition precursor comprises a first concentration of charged species and said first deposition medium comprises a second concentration of charged species.

17. The deposition apparatus of claim 16, wherein said second concentration of charged species is less than said first concentration of charged species.

18. The deposition apparatus of claim 17, wherein said second concentration is less than 100 ppm.

19. The deposition apparatus of claim 17, wherein said second concentration is less than 10 ppm.

20. The deposition apparatus of claim 17, wherein said second concentration is less than 1 ppm.

21. The deposition apparatus of claim 1, further comprising a second deposition chamber, said second deposition chamber equipped to form a second thin film material on said moving substrate.

22. The deposition apparatus of claim 21, wherein second deposition chamber comprises a second remote plasma source, said second remote plasma receiving a second deposition precursor, said second remote plasma source forming a second deposition medium from said second deposition precursor and directing said second deposition medium toward said moving substrate, said second deposition medium forming said second thin film material on said moving substrate.

23. The deposition apparatus of claim 22, wherein said second deposition precursor comprises silicon, germanium, hydrogen, or fluorine.

24. The deposition apparatus of claim 22, wherein said first thin film material is an intrinsic semiconductor and said second thin film material is an n-type or p-type semiconductor.

25. The deposition apparatus of claim 1, wherein the pressure within said first deposition chamber is less than the pressure within said first remote plasma source.

26. The deposition apparatus of claim 25, wherein the pressure within said first deposition chamber is at least a factor of 100 less than the pressure within said first remote plasma source.

27. A thin film deposition apparatus comprising:
a first deposition chamber;
a first remote plasma source operatively connected to said first deposition chamber, said remote plasma source receiving a first deposition precursor, said first remote plasma source forming a first deposition medium from said first deposition precursor;
an inlet spaced apart from said first remote plasma source and attached to said first deposition chamber, said inlet delivering a first deposition precursor to said first deposition chamber; and
a substrate in motion in said first deposition chamber, said substrate being spaced apart from said first remote plasma source and said inlet, said first remote plasma source directing said first deposition medium toward said first deposition precursor, said first deposition medium energizing said first deposition precursor, said energized first deposition precursor forming a first thin film material on said moving substrate.

28. The deposition apparatus of claim 27, wherein said first remote plasma source is operatively connected to said first deposition chamber with an orifice, said first remote plasma source directing said first deposition medium into said first deposition chamber through said orifice.

29. The deposition apparatus of claim 28, wherein said first remote plasma source is operatively connected to said first deposition chamber with a nozzle, said nozzle including said orifice.

30. The deposition apparatus of claim 27, wherein said first deposition precursor comprises silicon, germanium, hydrogen, or fluorine.

31. The deposition apparatus of claim 30, wherein said first deposition precursor comprises silane, fluorinated silane, disilane, fluorinated disilane, germane or fluorinated germane.

32. The deposition apparatus of claim 27, wherein said first thin film material includes amorphous regions.

33. The deposition apparatus of claim 27, wherein said first thin film material includes nanocrystalline or microcrystalline regions.

34. The deposition apparatus of claim 27, wherein said first thin film material is an intrinsic semiconductor.

35. The deposition apparatus of claim 27, wherein said first thin film material is an n-type or p-type semiconductor.

36. The deposition apparatus of claim 27, wherein said first remote plasma source includes a first electrode and a second electrode, said first remote plasma source including a first plasma region between said first electrode and said second electrode, said first remote plasma source activating said first deposition precursor in said first plasma region, said activated first deposition precursor exiting said first plasma region, said exiting first deposition precursor providing said first deposition medium.

37. The deposition apparatus of claim 36, wherein said first remote plasma source is operatively connected to said first deposition chamber with a nozzle, said nozzle including said orifice.

38. The deposition apparatus of claim 37, wherein said first electrode comprises said orifice.

39. The deposition apparatus of claim 36, wherein said activated first deposition precursor comprises a plasma.

40. The deposition apparatus of claim 39, wherein said plasma is a thermal plasma.

41. The deposition apparatus of claim 36, wherein said activated first deposition precursor deactivates upon said exiting said first plasma region, said first deposition medium comprising said deactivated first deposition precursor.

42. The deposition apparatus of claim 36, wherein said activated first deposition precursor comprises a first concentration of charged species and said first deposition medium comprises a second concentration of charged species.

43. The deposition apparatus of claim 42, wherein said second concentration of charged species is less than said first concentration of charged species.

44. The deposition apparatus of claim 43, wherein said second concentration is less than 100 ppm.

45. The deposition apparatus of claim 43, wherein said second concentration is less than 10 ppm.

46. The deposition apparatus of claim 43, wherein said second concentration is less than 1 ppm.

47. The deposition apparatus of claim 27, further comprising a second deposition chamber, said second deposition chamber equipped to form a second thin film material on said moving substrate.

48. The deposition apparatus of claim 47, wherein second deposition chamber comprises a second remote plasma source, said second remote plasma receiving a second deposition precursor, said second remote plasma source forming a second deposition medium from said second deposition precursor and directing said second deposition medium toward said moving substrate, said second deposition medium forming said second thin film material on said moving substrate.

49. The deposition apparatus of claim 48, wherein said second deposition precursor comprises silicon, germanium, hydrogen, or fluorine.

50. The deposition apparatus of claim 48, wherein said first thin film material is an intrinsic semiconductor and said second thin film material is an n-type or p-type semiconductor.

51. The deposition apparatus of claim 27, wherein the pressure within said first deposition chamber is less than the pressure within said first remote plasma source.

52. The deposition apparatus of claim 51, wherein the pressure within said first deposition chamber is at least a factor of 100 less than the pressure within said first remote plasma source.
